(19) United States
(12) Patent Application Publication
(10) Pub. No.: US 2001/0034124 A1
(43) Pub. Date: Oct. 25, 2001

(54) Method and system for improving the dimensional accuracy of core source/drain marks

(76) Inventors: Michael K. Templeton, Atherton, CA (US); Hao Fang, Cupertino, CA (US); Mark S. Chang, Los Altos, CA (US)

Correspondence Address: Joseph A. Sawyer Jr., SAWYER LAW GROUP LLP, P.O. Box 51418, Palo Alto, CA, 94303, US

(21) Appl. No.: 09/788,186

(22) Filed: Feb. 15, 2001

Related U.S. Application Data
(60) Provisional application No. 60/183,115, filed on Feb. 17, 2000.

(51) Int. Cl. H01L 21/44

(52) U.S. Cl. 438/669

(57) ABSTRACT

A method and system for providing a plurality of lines in a core of a memory device from a layer of material is disclosed. The method and system include utilizing a mask to print a physical mask for the plurality of lines. The mask includes a plurality of polygons for each of the plurality of lines. The plurality of polygons are for printing a pattern for the physical mask, the pattern of the physical mask covering a first portion the layer of material. In one aspect, the plurality of polygons includes a first polygon having at least one end and at least one hammerhead structure at the at least one end. In another aspect, the plurality of polygons includes a first polygon having at least one end and at least one serit structure at the at least one end. The method and system also include removing a second portion of the layer of material exposed by the pattern of the physical mask to form the plurality of lines. Thus, the plurality of lines has reduced foreshortening and reduced end-rounding.

### FIELD OF THE INVENTION

The present invention relates to semiconductor devices, particularly memory devices, and more particularly to a method and system for more reducing undesired optical effects in polysilicon lines.

### BACKGROUND OF THE INVENTION

Currently, semiconductor memory devices are used for many applications. Semiconductor memory devices typically include a central, core region and an outer logic region. The core region of the semiconductor memory device typically includes memory cells used for storing information. Memory cells typically include floating gates made of first polysilicon lines formed from a first layer of polysilicon, control gates made of polysilicon word lines formed from a second layer of polysilicon and an insulating layer that separates the control gates from the floating gates. The floating gates are typically separated from the semiconductor substrate by a gate dielectric layer.

FIG. 1 depicts a conventional method 10 for providing polysilicon lines, such as the first or second polysilicon lines, in a memory device, such as a NAND memory device. The conventional method 10 commences after the first or second polysilicon layer, which is to be etched, is provided on the semiconductor substrate. A conventional mask for use in printing a conventional pattern on a layer of photoresist is provided, via step 12. The conventional mask has a single polygon, or line, for each line to be provided in the polysilicon layer.

FIG. 2A depicts a conventional mask 30 provided in step 12 of the method 10. The mask 30 includes polygons 32, 34 and 36 for providing three lines in the polysilicon of a memory device. Thus, the conventional mask 30 includes a single polygon for each line to be provided.

Referring back to FIG. 1, a layer of photoresist is deposited on the polysilicon layer which is to be etched, via step 14. Using the mask provided in step 12, a conventional pattern is printed onto the photoresist layer using the mask 30. Thus, a conventional physical mask is thus provided.

FIG. 2B depicts the conventional physical mask 40 provided. The conventional physical mask 40 is a photoresist. The conventional physical mask 40 includes lines 42, 44 and 46 which cover portions of the underlying polysilicon layer (not explicitly shown).

Referring back to FIG. 1, a portion of the underlying polysilicon layer is removed while the conventional physical mask covers the underlying polysilicon layer, via step 18. Thus, only the portion of the polysilicon layer that is exposed is removed in step 18.

FIG. 2C depicts a portion the core of the NAND memory device 50. The NAND memory device 50 includes first conventional polysilicon lines 52, 54 and 56. Thus, conventional polysilicon lines can be provided on a conventional memory device 50.

Although the method 10 functions, one of ordinary skill in the art will readily realize that the conventional polysilicon lines 52, 54 and 56 do not have the desired shape. Because of optical effects encountered when the mask 30 is used to print the conventional pattern for the conventional physical mask 40. In particular, optical effects cause the lines 42, 44 and 46 corresponding to polygons 32, 34 and 36, respectively, to be foreshortened and rounded. This can be seen by comparing the polygons 32, 34 and 36 with the lines 42, 44 and 46. The lines 42, 44 and 46 of the conventional physical mask are shorter than the polygons 32, 34 and 36. Furthermore, the ends of the liens 42, 44 and 46 are rounded. In contrast, the ends of polygons 32, 34 and 36 have sharp corners. Because the conventional physical mask 40 has lines 42, 44 and 46 which are rounded and foreshortened, the polysilicon lines 52, 54 and 56 are also rounded and foreshortened. Thus, the polysilicon liens 52, 54 and 56 do not have the desired dimensions. In particular, the shape and length of the polysilicon lines 52, 54 and 56 is different from what is desired.

In order to reduce foreshortening in the memory core it is known to make the polygons 32, 34 and 36 longer. Such a mask would reduce or eliminate foreshortening of the lines 42, 44, 46 and polysilicon lines 52, 54 and 56. However, using longer polygons in place of the polygons 32, 34 and 36 does not reduce the rounding at the ends of lines 42, 44 and 46 or lines 52, 54 and 56. For logic devices, which may be included at the periphery of the memory device, it is known to use multiple polygons in a mask, such as a hammerhead structure, in order to compensate for optical effects. However, such techniques are typically not used in the core region for forming polysilicon lines 52, 54 and 56, such as the first polysilicon lines used for the floating gates.

Accordingly, what is needed is a system and method for providing lines in the core region which have improved dimension accuracy and, therefore, reduced foreshortening and end-rounding. The present invention addresses such a need.

### SUMMARY OF THE INVENTION

A method and system for providing a plurality of lines in a core of a memory device from a layer of material is disclosed. The method and system comprise utilizing a mask to print a physical mask for the plurality of lines. The mask includes a plurality of polygons for each of the plurality of lines. The plurality of polygons are for printing a pattern for the physical mask, the pattern of the physical mask covering a first portion the layer of material. In one aspect, the plurality of polygons includes a first polygon having at least one end and at least one hammerhead structure at the at least one end. In another aspect, the plurality of polygons includes a first polygon having at least one end and at least one serit structure at the at least one end. The method and system also comprise removing a second portion of the layer of material exposed by the pattern of the physical mask to form the plurality of lines. Thus, the plurality of lines has reduced foreshortening and reduced end-rounding.

According to the system and method disclosed herein, the present invention provides lines in which the foreshortening and rounding of the ends of the lines may be significantly reduced.

### BRIEF DESCRIPTION OF THE DRAWINGS

FIG. 1 is a flow chart depicting a conventional method for providing lines in a memory core for a conventional memory device.

FIG. 2A is a diagram of a conventional mask.

FIG. 2B is a diagram of a conventional physical mask.

FIG. 2C is a diagram of a portion of a core of conventional memory device.

FIG. 3 is a high-level flow chart of one embodiment of a method in accordance with the present invention for providing lines in the core of a memory device.

FIG. 4 is a flow chart of a preferred embodiment of a method in accordance with the present invention for providing lines in the core of a memory device.

FIG. 5A is a diagram of a mask formed in accordance with the present invention.

FIG. 5B is a diagram of a physical mask formed in accordance with the present invention.

FIG. 5C is a diagram of a portion of a core of a memory device formed in accordance with the present invention.

FIG. 5D depicts a portion of a core of the memory device formed in accordance with the present invention.

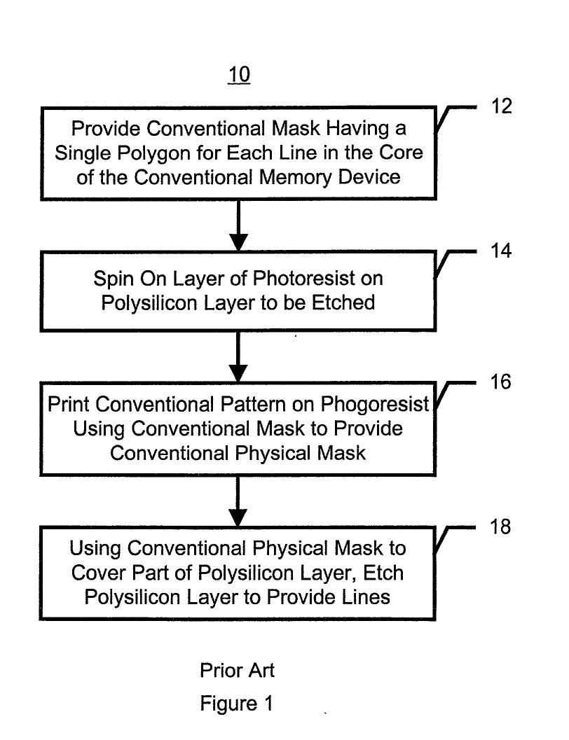

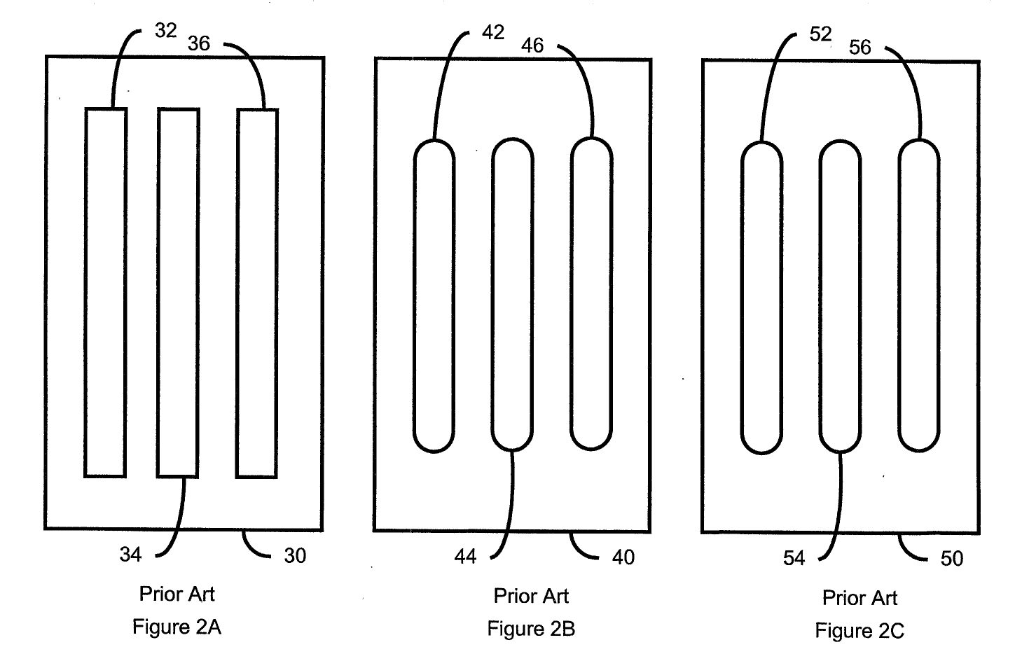

### DETAILED DESCRIPTION OF THE INVENTION

The present invention relates to an improvement in semiconductor memory devices. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown, but is to be accorded the widest scope consistent with the principles and features described herein.

Cores of conventional memory devices, such as the cores of conventional NAND devices, include conventional lines, such as the first or second polysilicon lines which are used for the floating gates. In order to fabricate the lines in the core, a conventional mask is used. The conventional mask includes a single polygon for each of the conventional lines to be formed. The polygon typically has the desired dimensions for the conventional lines. A layer of photoresist overlying the layer from which lines are to be formed is printed using the conventional mask. Thus, a conventional physical mask that is the image of the mask is printed onto the photoresist layer. Conventional lines in the physical mask which correspond to the polygons cover portions of the underlying layer that will become the conventional lines for the memory device. The portions of the underlying layer that are exposed by the conventional physical mask are removed. Thus, conventional lines are formed in the core of the conventional memory device.

Although conventional memory devices can be fabricated, one of ordinary skill in the art will readily realize that conventional lines in the core region of conventional memory devices often suffer from foreshortening and end-rounding. Thus, conventional lines, such as the first polysilicon lines, are shorter than desired. Furthermore, the ends of the conventional lines are rounded. These foreshortening and end-rounding are the consequences of optical effects. When a conventional mask having polygons with the desired dimensions for the lines is used to print a conventional physical mask on a layer of photoresist, the image of the conventional mask includes the optically-induced foreshortening and end-rounding. When the underlying layer, such as the first layer of polysilicon, is etched, the optical effects on the conventional physical mask are transferred to the polysilicon lines. Thus, the conventional lines are foreshortened, rounded, and do not have the desired shape and dimension.

A method and system for providing a plurality of lines in a core of a memory device from a layer of material is disclosed. The method and system comprise utilizing a mask to print a physical mask for the plurality of lines. The mask includes a plurality of polygons for each of the plurality of lines. The plurality of polygons are for printing a pattern for the physical mask, the pattern of the physical mask covering a first portion the layer of material. In one aspect, the plurality of polygons includes a first polygon having at least one end and at least one hammerhead structure at the at least one end. In another aspect, the plurality of polygons includes a first polygon having at least one end and at least one serit structure at the at least one end. The method and system also comprise removing a second portion of the layer of material exposed by the pattern of the physical mask to form the plurality of lines. Thus, the plurality of lines has reduced foreshortening and reduced end-rounding.

The present invention will be described in terms of particular processes and materials, such as photoresist and polysilicon lines. However, one of ordinary skill in the art will readily recognize that this method and system will operate effectively for other materials and other processes. The present invention is also described in terms of particular steps. However, one of ordinary skill in the art will readily realize that certain steps have been omitted for the purposes of clarity. The present invention will also be described in the context of providing first polysilicon lines in a preferred embodiment. However, one of ordinary skill in the art will readily realize that the method and system is consistent with providing other lines, such as the second polysilicon lines, in the core of memory semiconductor devices.

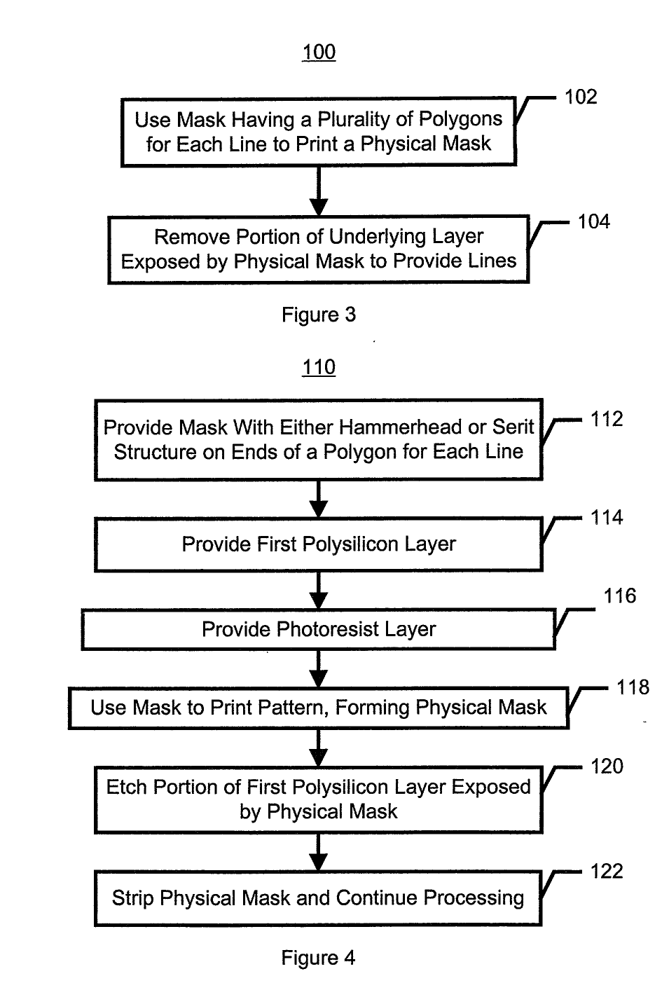

To more particularly illustrate the method and system in accordance with the present invention, refer now to FIG. 3, depicting a high-level flow chart of one embodiment of a method in accordance with the present invention for providing lines in the core of a memory device. A mask in accordance with the present invention is used for printing a pattern in a physical mask, via step 102. The mask utilized in step 102 has a plurality of polygons for each line to be provided. In one embodiment, the mask has a polygon with a hammerhead structure, discussed below, on each end for each line. In another embodiment, the mask has a polygon with a serit structure, also discussed below, on each end for each line. Also in a preferred embodiment, the polygons for which the hammerhead and serit structures are provided are longer than for a conventional mask. The mask is thus used to provide a physical mask that will expose portions of an underlying layer from which the lines are to be formed. A portion of the underlying layer is then removed to form the lines, via step 104.

Because the mask has a plurality of polygons for each line formed, the plurality of polygons can be used to compensate for optical effects such as foreshortening and end-rounding. For example, a single polygon can be used for most of each of the lines. The single polygon is thus used to provide a long thin line. Additional polygon(s) at the ends of the single polygon, as well as the extended length of single polygon, then compensate for foreshortening and end-rounding.

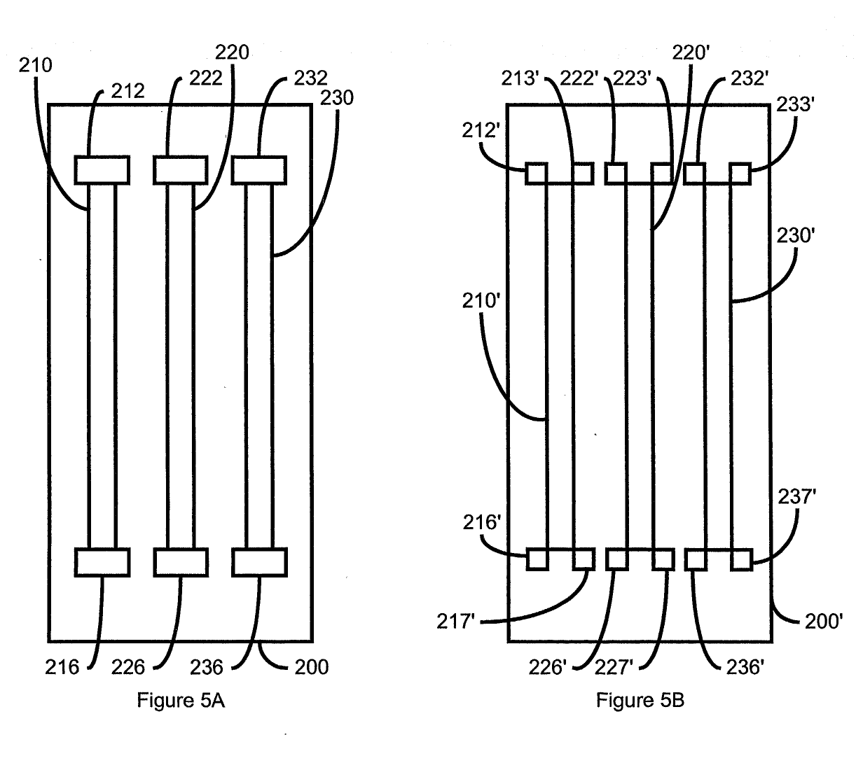

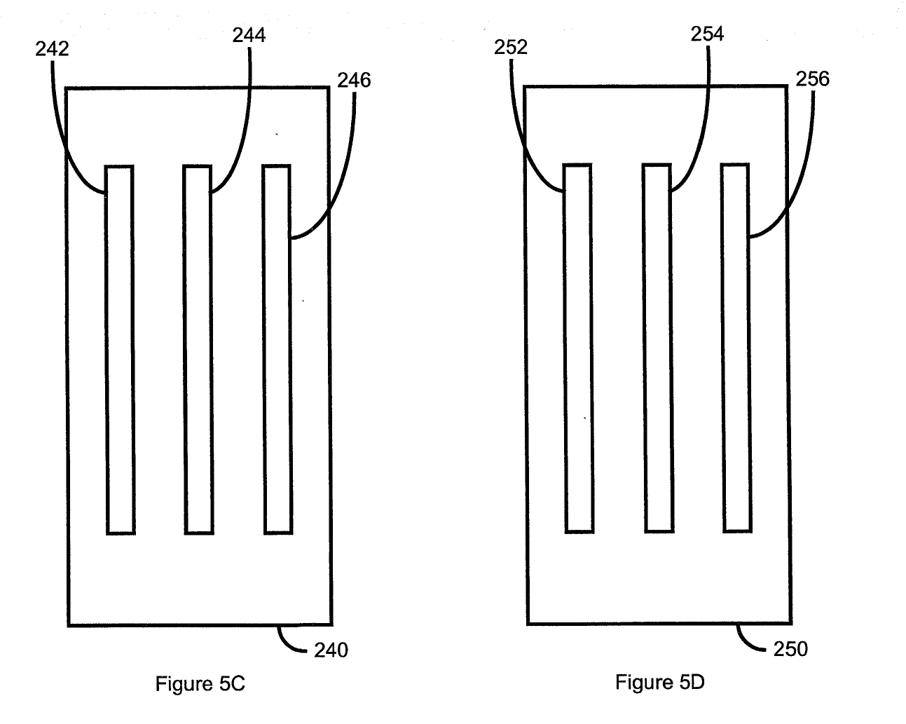

FIG. 4 depicts a more detailed flow chart of a preferred embodiment of a method 110 for providing lines in the core of a memory device. The method 110 in FIG. 4 is preferably used for providing the first polysilicon lines, which will be used to form floating gates for memory cells, in the core of NAND devices. However, the method 110 can be used for other polysilicon structures, such as the second polysilicon lines. The method 110 depicted in FIG. 4 will be described using FIGS. 5A through 5D. Although FIGS. 5A through 5D are also described in the context of providing first polysilicon lines, the present invention is consistent with providing other structures, such as the second polysilicon lines.

A mask having a hammerhead or a serit structure at the ends of a polygon for each line to be formed is provided, via step 112. In FIGS. 5A and 5B depicts masks 200 and 200′ having hammerhead and serit structures, respectively. Referring to FIG. 5A, three polygons 210, 220 and 230 for forming three lines are shown. In a preferred embodiment, the polygons 210, 220 and 230 are also longer than are provided in a conventional mask for lines in the core of the same length. The polygon 210 has a hammerhead structure formed by each of the polygons 212 and 216 at each end of the polygon 210. Similarly, the polygon 220 has a hammerhead structure formed by each of the polygons 222 and 226 at each end of the polygon 220. The polygon 230 has a hammerhead structure formed by each of the polygons 232 and 236 at each end of the polygon 230. FIG. 5B includes three polygons 210′, 220′ and 230′ for forming three lines. In a preferred embodiment, the polygons 210′, 220′ and 230′ are also longer than are provided in a conventional mask for lines in the core of the same length. The polygon 210′ has a serit structure formed by the polygons 212′ and 213′ and by the polygons 216′ and 217′ at each end of the polygon 210′. Similarly, the polygon 220′ has a serit structure formed by the polygons 222′ and 223′ and by the polygons 226′ and 227′ at each end of the polygon 220′. The polygon 230′ has a serit structure formed by the polygons 232′ and 233′ and by the polygons 236′ and 237′ at each end of the polygon 230′. Referring to FIGS. 5A and 5B, the masks 200 and 200′ thus include a plurality of polygons for each line to be formed. In a preferred embodiment, the polygons 210, 220, 230, 210′, 220′ and 230′ are slightly longer than the desired length for the first polysilicon lines.

Referring back to FIG. 4, a first polysilicon layer is provided on the memory device, via step 114. A photoresist layer is provided on the polysilicon layer, via step 116. The mask 200 or 200′ is then used to print a pattern on the photoresist layer in order to provide a physical mask on the first polysilicon layer, via step 118.

FIG. 5C depicts the physical mask 240 provided using step 118. The physical mask 240 includes lines 242, 244 and 246, which cover the portions of the first polysilicon layer which will be become the first polysilicon lines. Because of the hammer head and serit structures of the masks 200 and 200′, and preferably because of the extended length of polygons 210, 220 and 230 and polygons 210′, 220′ and 230′, respectively, the lines 242, 244 and 246 of the physical mask 240 have reduced foreshortening and end-rounding. In a preferred embodiment, the foreshortening and end rounding can be prevented. Thus, the polygons 212, 216, 222, 226, 232 and 236 forming the hammerhead structures and the polygons 212′, 213′, 216′, 217′, 222′, 223′, 226′, 227′, 232′, 233′, 236′ and 237′ forming the serit structures can compensate for optical effects, allowing for the reduce foreshortening and end-rounding in the physical mask 240.

Referring back to FIG. 4 the first polysilicon layer is etched while the physical mask 240 covers a portion of the first polysilicon layer, via step 120. A portion of the first polysilicon layer that is not covered by the physical mask 240 is removed in step 120. Therefore, the first polysilicon lines are formed. The physical mask 240 is stripped after the etch in step 120 is completed and processing continues, via step 122.

FIG. 5D depicts a portion of a core 250 of the memory device. The core 250 includes first polysilicon lines 252, 254 and 256. The first polysilicon lines 252, 254 and 256 were covered by lines 242, 244 and 246, respectively, of the physical mask 240 depicted in FIG. 5C. Referring back to FIG. 5D, the first polysilicon lines 252, 254 and 256 have reduced foreshortening and end-rounding. The foreshortening and end-rounding can, therefore, be minimized. Optical effects in the polysilicon lines 252, 254 and 256 are thereby reduced. Thus, the dimensions of the first polysilicon lines 252, 254 and 256 have close to the desired dimensions. Consequently, use of hammerhead or serit structures in the masks 200 and 200′, as well as the use of longer polygons 210, 220 and 230 and polygons 210′, 220′ and 230′, respectively, can reduce or eliminate end-rounding and foreshortening, thereby providing lines in the core 250 of the memory device which have the desired dimensions.

A method and system has been disclosed for providing lines having reduced optical effects, such as end-rounding and foreshortening, in a core of a memory device. Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for providing a plurality of lines in a core of a memory device from a layer of material, the method comprising the steps of:
(a) utilizing a mask to print a physical mask for the plurality of lines, the mask including a plurality of polygons for each of the plurality of lines, the plurality of polygons printing a pattern for the physical mask, the pattern of the physical mask covering a first portion the layer of material; and
(b) removing a second portion of the layer of material exposed by the pattern of the physical mask to form the plurality of lines;
wherein foreshortening and end-rounding of the plurality of lines can be minimized.

2. The method of claim 1 wherein the plurality of polygons includes a first polygon having at least one end and at least one hammerhead structure at the at least one end.

3. The method of claim 1 wherein the plurality of polygons includes a first polygon having at least one end and at least one serit structure at the at least one end.

4. The method of claim 1 wherein the plurality of lines is a plurality of polysilicon lines.

5. The method of claim 4 wherein the layer of material is a first polysilicon layer and wherein the plurality of polysilicon lines is for a plurality of floating gates.

6. A semiconductor memory device comprising:
a semiconductor substrate;
a memory core, the memory core including a plurality of lines device from a layer of material, the plurality of lines formed by utilizing a mask to print a physical mask for the plurality of lines, the mask including a plurality of polygons for each of the plurality of lines, the plurality of polygons printing a pattern for the physical mask, the pattern of the physical mask covering a first portion the layer of material and by removing a second portion of the layer of material exposed by the pattern of the physical mask to form the plurality of lines;
wherein foreshortening and end-rounding of the plurality of lines can be minimized.

7. The semiconductor memory device of claim 6 wherein the plurality of polygons includes a first polygon having at least one end and at least one hammerhead structure at the at least one end.

8. The semiconductor memory device of claim 6 wherein the plurality of polygons includes a first polygon having at least one end and at least one serit structure at the at least one end.

9. The semiconductor memory device of claim 6 wherein the plurality of lines is a plurality of polysilicon lines.

10. The semiconductor memory device of claim 9 wherein the layer of material is a first polysilicon layer and wherein the plurality of polysilicon lines is for a plurality of floating gates.

11. The semiconductor memory device of claim 6 wherein the semiconductor memory device is a NAND device.
